(19) United States
(12) Patent Application Publication
(10) Pub. No.: US 2011/0023970 A1
(43) Pub. Date: Feb. 3, 2011

(54) DEVICE FOR CREATING A MICROFLUIDIC CHANNEL STRUCTURE IN A CHAMBER

(75) Inventors: Bastian RAPP, Karlsruhe (DE); Achim VOIGT, Eggenstein-Leopoldshafen (DE); Leonardo CARNEIRO, Belo Horizonte (BR)

Correspondence Address: Leydig, Voit & Mayer, Ltd. (Frankfurt office), Two Prudential Plaza, Suite 4900, 180 North Stetson Avenue, Chicago, IL, 60601-6731, US

(73) Assignee: KARLSRUHER INSTITUT FUER TECHNOLOGIE, Karlsruhe (DE)

(21) Appl. No.: 12/844,181

(22) Filed: Jul. 27, 2010

(30) Foreign Application Priority Data
Jul. 30, 2009 (DE) 10 2009 035 291.0

(51) Int. Cl. B81B 1/00

(52) U.S. Cl. 137/13; 137/341

(57) ABSTRACT

A device for creating a microfluidic channel structure includes two plates forming a chamber between the two plates. The chamber has at least one inlet for feeding a fluid into the chamber and at least one outlet for discharging the fluid out of the chamber. A cooling element is associated with at least one of the two plates for converting fluid disposed in the chamber into a solid. A plurality of heating elements is associated with at least a first of the two plates and distributed so as to provide, by a heating up of some of the heating elements so as to convert areas of the solid that are in a vicinity of the heating elements to the fluid, a channel structure leading from the at least one inlet through the chamber to the at least one outlet. The channel structure is configured to convey fluid flow.

### CROSS REFERENCE TO RELATED APPLICATIONS

This application claims priority to German Patent Application No. DE 10 2009 035 291.0, filed on Jul. 30, 2009.

### FIELD

The invention relates to a device for creating a microfluidic channel structure in a chamber that forms a cavity between two plates to receive a fluid; it also relates to a method for its production and to its use.

### BACKGROUND

As a rule, microfluidic systems have a microfluidic channel structure designed according to its use and configured in a solid substrate, especially made of silicon, metal, ceramic or polymer. This structure is usually created by means of technical methods used for microsystems such as, for example, lithography, followed by an etching process or by a silicon surface technique. For polymers, replication techniques such as injection molding and hot-stamping are often employed. All of these methods have in common the fact that the structure created with them is unchangeable, that is to say, the precise dimensions, the geometry and the design of the structure all have to be determined before they are created and can no longer be changed after the fact.

Suggestions have already been made that deal with the aspect of programming a microfluidic structure. International patent application WO 2007/012638 A1 describes a device with which droplets of a liquid are moved over electric contacts due to electrowetting, and the wetting tendency of the drops is changed because of the voltages present and the resulting field strengths. In this manner, a drop can be moved over an array of electric contacts.

Furthermore, some devices work with surfaces that have been chemically or physically modified in different ways and that change the wetting tendency of a drop. These include surfaces with nanostructures that make use of the so-called lotus effect, as well as devices that work with surface charges or chemical hydrophobization (International patent application WO 2007/090531 A1).

These devices, however, do not create a microfluidic structure in the true sense of the word, they only move a certain quantity of a fluid. These systems lend themselves for the discrete manipulation of fluids in the form of drops, but not for the application of pressure or for the continuous flow of fluids, as is usefeul in almost all biosensors. Moreover, such devices are very sensitive to pressure fluctuations since the states of equilibrium and the holding forces exerted by the surfaces are very small. Consequently, it is difficult to introduce larger quantities of fluid into these devices. Moreover, when it comes to biomedical applications, they are often not suitable because the interaction surfaces or the surfaces are strongly wetted. As a consequence, proteins and comparable biomolecules often accumulate on these surfaces, which alters the concentration of the fluids and causes contamination of the specimen due to cross-contamination. Furthermore, the individual fluid droplets in these systems are separated from each other only by air; it is thus not possible to counter the evaporation and cross-contamination, which is why these systems are unsuitable for critical biomedical applications.

Another group of devices for creating programmable microfluidic structures are systems having membrane valves. In “Electrostatically driven elastomer components for user-reconfigurable high-density microfluidics” Lab Chip 9, pages 1274 to 1281, 2009, M.-P. Chang and M. M. Maharbiz describe systems that employ actuators on the basis of deflectable membranes, primarily made of silicon (polydimethylsiloxane, PDMS).

The described system creates the channel structure thermally; there is no need for active moving components, which allows the system to be scaled to any desired size without problems. The only limiting factor is the physical dimensions of the heating elements; if their dimensions are smaller, more programmable elements can be accommodated on a surface. The packing density of these passive structures will always be greater than the packing density of a comparable system having active structures such as, for instance, membrane valves.

This, however, has the drawback that the structures are not freely programmable in the actual sense of the word, but rather, have to be determined in advance on the basis of the shape of the valves. This greatly restricts a free selection of the microfluidic structures since the valve structures cannot be packed densely at will. Moreover, the choice of materials that are suitable for this type of valves is substantially limited; in most cases, only silicones are a possibility. These materials only lend themselves to a limited extent when it comes to critical applications in biomedical technology, especially due to their tendency to swell in water and to the high adsorption of biomolecules. Another disadvantage is the unreliability of these valve structures, which becomes a problem if a large number of these valves is needed for a programmable structure. Moreover, silicones are permeable to gas, which allows the evaporation of fluids within the microfluidic structures, thus changing the concentration of the solutions over the course of time. This is extremely critical in the case of analytical applications.

U.S. pat. appl. no. 2008/0164155 A1 and international patent application WO 2008/117209 A1 describe devices for thermal management in microfluidic systems. In these cases, chemical or biological reactions are developed or regulated in a microfluidic system, for example, the replication of a DNA by means of polymerase chain reaction (PCR). None of these systems, however, uses heat management in order to create a microfluidic channel structure in the actual sense of the word.

U.S. pat. appl. no. 2009/0044875 A1 describes a device for creating a microfluidic channel structure in which a plurality of heating elements distributed over the device open and close various fluid channels by suitably switching the heating elements, whereby, under the effect of heat, the channels are closed due to the swelling of the channel walls that are made of a suitable polymer.

U.S. pat. appl. no. 2007/0227592 A1 describes a valve for controlling the flow through a microfluidic device. When the valve is heated up, the material of which the valve is made expands and blocks the flow through a selected channel.

U.S. pat. appl. no. 2003/0106596 A1 describes a microfluidic system for controlling the feed and the mixing of fluids that respond to temperature changes. For this purpose, each inlet channel has a valve with an enclosed heating element. When at least one valve is heated up, the viscosity of the fluid contained in it changes and so thus also the flow through the appertaining channel.

U.S. pat. appl. no. 2005/0236056 A1 describes a valve that is operated through freezing and heating up and that comprises a Peltier element.

### SUMMARY

In an embodiment, the present invention provides a device for creating a microfluidic channel structure. The device includes two plates forming a chamber between the two plates. The chamber has at least one inlet for feeding a fluid into the chamber and at least one outlet for discharging the fluid out of the chamber. A cooling element is associated with at least one of the two plates for converting fluid disposed in the chamber into a solid. A plurality of heating elements is associated with at least a first of the two plates and distributed so as to provide, by a heating up of some of the heating elements so as to convert areas of the solid that are in a vicinity of the heating elements to the fluid, a channel structure leading from the at least one inlet through the chamber to the at least one outlet. The channel structure is configured to convey fluid flow.

### BRIEF DESCRIPTION OF THE DRAWINGS

Embodiments of the invention will be explained in greater detail below with reference to the drawings, in which:

FIG. 1 shows a schematic set-up of a device for thermally creating microfluidic channel structures;

FIG. 2 shows a device for thermally creating microfluidic channel structures with a sketched connection strip;

FIG. 3 shows (a) a front view and (b) a side view (section) of the device for thermally creating microfluidic channel structures with an eliminated channel structure;

FIG. 4 shows (a) a front view and (b) a side view (section) of the device for thermally creating microfluidic channel structures with a created channel structure;

FIG. 5 shows a schematic top view of the device for thermally creating microfluidic channel structures, (a) selected heating elements are switched on, as a result of which, as shown in (b), a corresponding microfluidic channel structure can be opened.

### DETAILED DESCRIPTION

In an embodiment, an aspect of the invention is to provide a device for creating a microfluidic channel structure in a chamber that forms a cavity between two plates to receive a fluid, a method for its production and its use, all of which do not entail the above-mentioned drawbacks and limitations.

In one embodiment the device provides freely programmable microfluidic channel structures that can be created and, if so desired, also subsequently altered.

In order to create microfluidic channel structures, the device according to an embodiment of the invention utilizes the principle of changing the physical properties of a fluid, especially of a liquid, by raising and lowering the temperature.

The device includes a chamber that forms a cavity between two preferably flat plates. A plurality of heating elements is distributed over at least one of these plates, for which purpose a printed circuit board may be employed. The heating elements are preferably in the form of small heat resistors and are can be configured as an ohmic resistor or as a diode.

The at least one plate can have a structured network consisting of conductor paths that serve to actuate the heating elements. In one embodiment, this network structure is separated from the plate by a thin cover structure.

In an embodiment, the heating elements are individually contacted through galvanic contacting and can thus be switched on and off independently of each other. The galvanic contacting can be done ethrough at least one layer on the plate onto which the network structure of the conductor paths has been applied.

In an embodiment, the arrangement of the heating elements matches an arrangement of the type employed in classic electronic bar displays. Until the advent of LCD technology, information was depicted in these electronic bar displays in the form of letters and numbers. Microfluidic channel structures can be created, altered and employed in the same manner in embodiments of the present invention.

Underneath the plate on which the heating elements have been installed, or alternatively on the opposite plate, there is a cooling element as a heat sink, preferably in a flat embodiment. Cooling fin structures with a connected heat pipe, ventilation systems or Peltier elements are particularly suitable for this purpose.

A method according to an embodiment of the invention for creating and altering a microfluidic channel structure in a chamber that forms a cavity between two plates to receive a fluid comprises the steps a) through c).

According to step a), a fluid, that is to say, a liquid or a gas, is fed into the chamber through one or more inlets; it may be completely filled with the fluid.

The following provides examples of the fluid:
a liquid polymer, such as a thermoplastic, which may be a polymethylmethacrylate (PMMA) or polycarbonate (PC),
a liquid hydrocarbon, such as tetradecane (C₁₄H₃₀) or highly fluorinated hydrocarbons such as, for instance, thermal oils, or
a solution consisting of a mediating medium or separating medium that may be especially well-suited for applications in medical technology or in biotechnology. Alternatively, the chamber is filled with a gas.

Subsequently, according to step b), the fluid, that is to say, the gas or the liquid, is converted to the solid state in the chamber by means of a cooling element that is located on at least one of the two plates. For this purpose, heat is extracted from the fluid, preferably continuously, by switching on the cooling element, which functions like a heat sink. This causes the gas or liquid to solidify due to the effect of the temperature, either through freezing or sublimation, due to a chemical conversion, especially crystallization, or else due to the lowering of the temperature of a thermoplastic polymer melt to below its glass transition point. The fluid in this form constitutes a solid in which the microfluidic channel structures can be created.

In the subsequent step c), some of the plurality of heating elements that are distributed over the same plate or over the other plate are selectively switched on. During operation, the selected heating elements heat up. Owing to the resulting generation of heat around the heating elements, the above-mentioned solidification process of the fluid in the chamber is locally reversed. The solid thus liquefies or evaporates, reverting to the state that had been selected, particularly by reheating the polymer melt to above its glass transition point. As a result, an area of the solidified fluid around the selectively chosen heating elements once again becomes locally liquefied. In this manner, a channel structure leading from the inlet or inlets to the outlet or outlets is formed in the chamber and it is suitable for conveying a fluid flow through the chamber. An externally installed pump can be used to partially or completely empty the liquid or gas out of the chamber via the thus created channel structure via the defined inlets and outlets of the chamber in the connection strip, and can then be once again filled with the same fluid or with one or more other fluids.

In an embodiment, in an additional step d), which follows step c), the heating up of at least another part of the plurality of heating elements is terminated, as a result of which the layout of the channel structure changes due to solidification.

In an embodiment, a photoreactively cross-linkable polymer is employed as the fluid that, after step c) or d), is solidified through exposure to light and through the associated cross-linking of the polymer. Here, in particular, some of the solidified polymer is once again dissolved through exposure to light or through the action of solvents, as a result of which the layout of the channel structure changes.

As a function of the fluid selected in the chamber and of the corresponding physical or chemical effect of the solidification of this fluid, the following procedure is carried out after the microfluidic channel structure has been created:

1) Thermally unstable structure: the selected fluid requires the thermal management to be maintained, so that the heat sources and the heat sink have to be kept in operation constantly in order to prevent an undesired re-solidification.
2) Thermally stable structure: the selected fluid does not require the heat flows to be maintained; the structure is stable and the additional heat feed and heat dissipation can be dispensed with.

Depending on the thermal stability, the created microfluidic channel structure can be employed in different forms.

In the case of a thermally unstable structure, the structure can be used directly for microfluidic applications while maintaining the heat flows. In this context, the channel structure can be changed during the experiment in the exact same manner, which opens up a hitherto unheard-of scope of possible applications. The thermal management here guarantees a very precise temperature control of all of the fluids being conveyed in the system, which can be a decisive advantage. However, the requisite temperature gradients might cause foreign liquids in the system to freeze, which is why some of such channel structures remain limited to those microfluidic applications in which the fluids being conveyed never come into direct contact with the walls of the system. Such applications are designated as droplet microfluidics and are widespread in the realm of high-throughput systems.

A thermally unstable structure is simple to eliminate. For this purpose, the system first is emptied of foreign liquids. The chamber can then be heated up, for example, by using the heat sink. If Peltier cooling is being used, the voltage on the Peltier block is merely inverted. In this manner, the entire content of the chamber liquefies and the microfluidic structure is eliminated once again. This structure can then be re-created according to the described process in that the fluid is then frozen once again.

Another possibility for use consists of fixing the thermally unstable structure in this state. If a photoreactively cross-linkable polymer is employed as the fluid, this can be done, for instance, by means of exposure to light and the associated cross-linking of the polymer. Such a structure is stable after the cross-linking, even after the heat flows of the system have been switched off. Such a system allows the inexpensive production of microfluidic components, in a manner similar to a 3D printer.

In the second case, which describes the use of a fluid with which a thermally stable structure is created, the structure can be eliminated if the stability of the created structure can be once again reversed through external effects, for example, through exposure to light or through the action of solvents. Otherwise, the structure may be able to be eliminated. However, it can then also be removed from the system and employed for other microfluidic applications. This would likewise provide a system for cost-effectively and quickly producing microfluidic components in a manner similar to a 3D printer.

The device according to embodiments of the invention can be employed wherever microfluidic structures are used. Examples of this range from biosensor applications to synthesis applications, food-product and environmental technologies as well as similar applications. Of special relevance in this context are the lab-on-a-chip systems, in other words, fully integrated analysis systems on a microtechnical scale.

The aspect of exact temperature control for the created microfluidic channel structure can be a welcome side effect of the proposed device, which is thus capable of serving as a host structure for purposes of carrying out experiments.

FIG. 1 schematically shows a device for thermally creating microfluidic channel structures. The device consists of a housing, that may be made of metal or plastic, having an incorporated chamber 6 into which a known volume of a liquid polymer, for instance, a thermoplastic such as polymethylmethacrylate (PMMA) or polycarbonate (PC), a liquid hydrocarbon (e.g. tetradecane C₁₄H₃₀), a solution, a mediating medium or a separating medium, is filled, of the type needed for applications in medical technology or in biotechnology. For this purpose, inlets and outlets 102 are connected to the chamber 6, through which the chamber can then be refilled and emptied as the need arises.

On at least one side of this chamber, there is a plate 2, which may be a printed circuit board, on which a plurality of heat sources 30-1 to 30-n are arranged that are preferably configured in the form of heating elements. Here, the plate 2 is designed in such a way that each of the heating elements (heat sources) 30-1 to 30-n is galvanically contacted individually. Towards this end, the plate 2 may have a structured conductor path network that is especially configured inside the planar structure over planes that are separately galvanically isolated. An example of this is a multilayer etched wiring board. The heating elements 30-1 to 30-n are configured as diodes or ohmic resistors, for example, in an SMD configuration. The appertaining galvanic contacting makes it possible to switch every single heating element on and off separately from all other heating elements by means of a suitable electric connection and a corresponding electric actuator.

Underneath the plate 2 or on the opposite plate 1 of the chamber, there is a cooling element configured as a heat sink. The cooling element can be in the form of a cooling fin structure with a connected heat pipe, or in the form of a ventilation system, a Peltier element or another physical or chemical cold source, for instance, an endothermic reaction, a cooling tank filled with liquid nitrogen or other gases. The chamber 6, the plate 2 and the heat sink can be arranged in such a way that they exhibit the smallest possible thermal resistance with respect to each other.

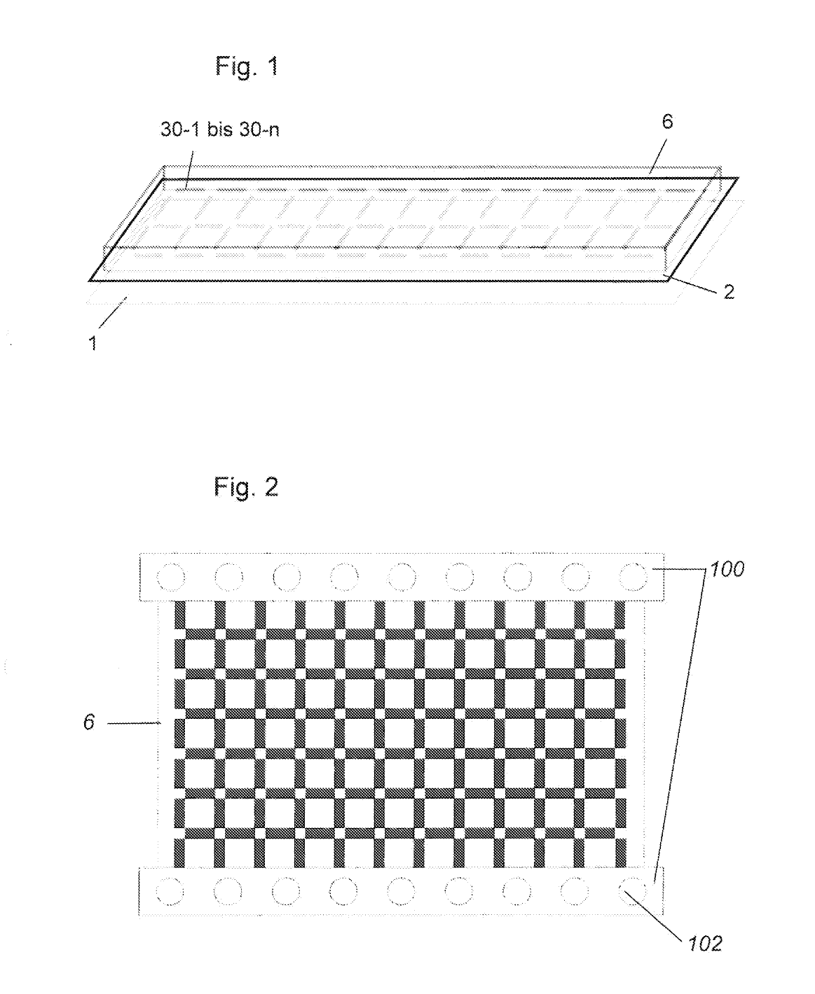

As shown in FIG. 2, the chamber 6 is fluidly contacted by inlets and outlets in order to ensure an exchange of the liquid medium in the chamber. For this purpose, the chamber has suitable connection strips 100, which can be made of polymer, metal or ceramic, which have the fluidic feed lines 102 leading to the chamber 6. The feed lines 102 are configured as fluidic coupling systems, for example as a luer connector or as an HPLC-capable connector with a thread and with suitable sealing surfaces. The system here has at least one inlet and at least one outlet.

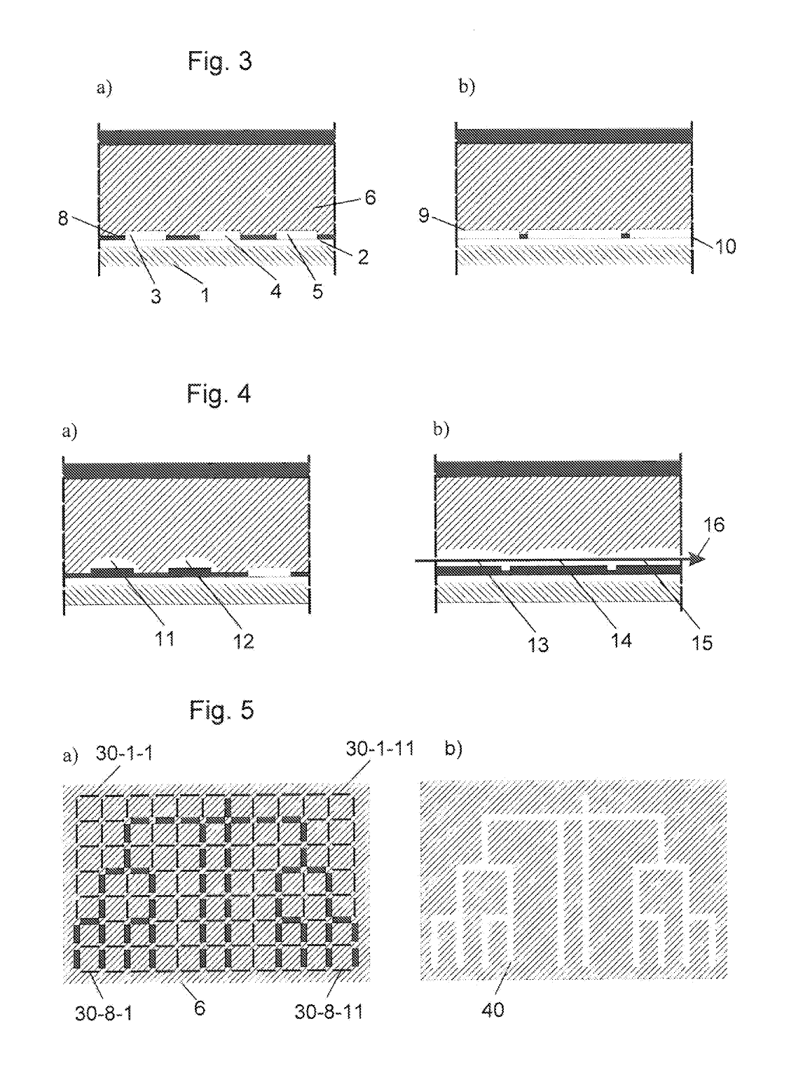

As shown in FIG. 3, the heat sink is operated constantly during operation, while the heating elements remain switched off. The heat dissipation through the plate 2 and through the heating elements 3, 4, 5, 9 and 10 causes the fluid in the chamber 6 to solidify due to the effect of the temperature, either as a result of freezing, chemical conversion, preferably crystallization, or as a result of the lowering of the temperature of a thermoplastic polymer melt to below its glass transition point. Owing to the cooling, the fluid thus temporarily becomes a solid. The implemented inlets and outlets 102 leading into the chamber 6 are thus closed, thereby preventing all fluid transport through the chamber 6.

In the second step, individual heating elements are now selectively energized via the plate 2 and via an appertaining electric actuator, as a result of which they heat up. FIG. 4 shows a situation in which the heating elements 3, 4, 9 and 10 have been energized. The generation of heat that takes place above the heating elements causes a local reversal of the above-mentioned process of solidification of the fluid in the chamber 6 due to the effect of the temperature. Therefore, the solid liquefies, reverting to the state that had been selected, for instance, by reheating the polymer melt above its glass transition point. As a result, an area of solidified fluid above each of the heating elements liquefies locally once again (cavities 11 and 12, respectively corresponding to the heating elements 3 and 4, as well as cavities 13, 14 and 15, respectively corresponding to the heating elements 4, 9 and 12).

In this context, it should be noted that the temperature distribution and the heat transport through the heat sink are selected in such a way that the cavities are created directly above the heating elements. A suitable selection of the individual heating elements and their parallel actuation can then ensure an appropriate linking of local liquefaction which allows the opening of a microfluidic channel structure from which, first of all, the fluid originally introduced into the chamber 6 can be removed by means of a flow 16 created by an external pump.

FIG. 5 shows the principle of the thermal creation of a variable microfluidic channel structure. The selection of the settings of the heating elements 30-1-1 to 30-8-11 makes it possible create a variable microfluidic structure 40 in the chamber 6, and this structure can be used for various microfluidic applications. These include analytical and combinatorial applications as well as syntheses. In this context, the arrangement of the channel structure 40 should be such that the fluidic connecting points 102 provided in the connection strip 100 are in communication with the microfluidic channel structure 40, as a consequence of which it can be filled, emptied and sampled at the desired place.

While the invention has been particularly shown and described with reference to preferred embodiments thereof, it will be understood by those skilled in the art that various changes in form and details may be made therein without departing from the spirit and scope of the invention.

1.-12. (canceled)

13. A device for creating a microfluidic channel structure comprising:
two plates forming a chamber between the two plates, the chamber having at least one inlet for feeding a fluid into the chamber and at least one outlet for discharging the fluid out of the chamber;
a cooling element associated with at least one of the two plates for converting fluid disposed in the chamber into a solid; and
a plurality of heating elements associated with at least a first of the two plates and distributed so as to provide, by a heating up of some of the heating elements so as to convert areas of the solid that are in a vicinity of the heating elements to the fluid, a channel structure leading from the at least one inlet through the chamber to the at least one outlet, the channel structure being configured to convey fluid flow.

14. The device recited in claim 13, wherein the first plate includes a structured network having conductor paths configured to actuate the heating elements.

15. The device recited in claim 14, wherein the structured network of conductor paths is disposed on galvanically isolated layers that form the first plate.

16. The device recited in claim 13, wherein the heating elements include at least one of an ohmic resistor and a diode.

17. The device recited in claim 13, wherein the cooling element includes a cooling fin structure having a connected heat pipe.

18. The device recited in claim 13, wherein the cooling element includes at least one of a ventilation system and a Peltier system.

19. A method of creating a microfluidic channel structure in a chamber, the method comprising:
providing a chamber between two plates, the chamber having at least one inlet and at least one outlet, at least one of the two plates including a cooling element, and a at least a first of the two plates includes a plurality of heating elements distributed thereover;
feeding a fluid into the chamber through the at least one inlet;
converting the fluid in the chamber to a solid using the cooling element; and
heating up at least some of the heating elements so as to convert areas of the solid in a vicinity of the respective heating elements to the fluid, so as to form a channel structure leading from the at least one inlet through the chamber to the at least one outlet so as to convey fluid flow.

20. The method recited in claim 19, further comprising terminating the heating up of a portion of the respective heating elements so as to change a layout of the channel structure by a resulting solidification of the fluid.

21. The method recited in claim 19, wherein the fluid includes at least one of a liquid polymer, a liquid hydrocarbon, a solution of a mediating medium, and a solution of separating medium.

22. The method recited in claim 19, further comprising removing at least a portion of the fluid converted by the heating up, and replacing the removed fluid with at least one other fluid.

23. The method recited in claim 19, wherein the fluid is a photoreactively cross-linkable polymer, and further comprising exposing at least a portion of the fluid converted by the heating up so as to form associated cross-linking of the polymer so as to solidify the polymer.

24. The method recited in claim 23, further comprising dissolving the solidified polymer through at least one of exposure to light and an action of solvents.

25. The method recited in claim 19, wherein the heating up is performed so as to convey the fluid flow so as to provide at least one of a high-throughput analysis, a high-throughput synthesis, a monitor technology, and a display technology.
